(19) United States
(12) Patent Application Publication
(10) Pub. No.: US 2011/0244393 A1
(43) Pub. Date: Oct. 6, 2011

(54) PHOTOSENSITIVE RESIN COMPOSITION AND METHOD FOR PRODUCING LIQUID DISCHARGE HEAD

(75) Inventor: Masumi Ikeda, Nishinomiya-shi (JP)

(73) Assignee: CANON KABUSHIKI KAISHA, Tokyo (JP)

(21) Appl. No.: 13/076,311

(22) Filed: Mar. 30, 2011

(30) Foreign Application Priority Data
Apr. 1, 2010 (JP) 2010-085464

(51) Int. Cl. G03F 7/004; G03F 7/20

(52) U.S. Cl. 430/270.1; 430/320

(57) ABSTRACT

A method for producing a liquid discharge head having a flow path wall member which includes walls of a liquid flow path communicating with discharge ports that discharge a liquid includes: preparing a substrate having a resin layer formed from a resin composition containing a polyhydroxystyrene-based resin in which the hydrogen atoms of phenolic hydroxyl groups are partially substituted with groups which are dissociable by acid, a compound having two or more vinyl ether groups, and a compound capable of generating a particular acid upon receiving energy from light; exposing the resin layer to light and removing exposed areas to form a pattern of the flow path from the resin layer; preparing a coating layer which serves as the flow path wall member; exposing the coating layer to light and removing unexposed areas of the coating layer to form openings that serve as the discharge ports; and removing the pattern.

### BACKGROUND OF THE INVENTION

1. Field of the Invention

The present invention relates to a photosensitive resin composition and a method for producing a liquid discharge head.

2. Description of the Related Art

A method for producing an inkjet recording head is discussed in U.S. Pat. No. 5,478,606 as an example of a liquid discharge head. This method involves, first of all, forming a pattern of flow path for ink using a resin composition that is removable by dissolution, on a substrate having an energy generation element which generates energy that is used to discharge a liquid, subsequently coating this pattern with a flow path wall-forming material which will serve as the walls of the flow path for ink, forming discharge ports in the flow path wall-forming material, and then dissolving the pattern to form a flow path. It is discussed that a positive photoresist is used as the resin composition that is removable by dissolution, and a cationically polymerizable type negative resist based on an epoxy resin is used as the flow path wall-forming material.

To improve the discharge performance of a liquid discharge head, there have been demands for arranging the flow path in a highly compact manner, or for increasing the positional accuracy of the flow path forming positions, to thereby make a high-precision flow path. It is believed that these demands will grow further in the future, concomitantly with an increase in the users' demand for color image recording of photographic quality.

In an attempt to satisfy the demands described above, it is desirable to form a pattern of flow path according to a photolithographic technique which uses a high-precision exposure apparatus of reduced projection type during the operation of liquid discharge head production. However, in regard to the positive resist used in U.S. Pat. No. 5,478,606, since the mechanism of the reaction to make the photoresist positive is based on a main chain decomposition reaction, the sensitivity is low when the photoresist is used as a thick film, and the photoresist requires a very long exposure time at an amount of exposure that can be conventionally output by an exposure apparatus of reduced projection type.

Thus, the inventor of the present invention newly examined the possibility of producing a liquid discharge head by the method discussed in U.S. Pat. No. 5,478,606, using the chemically amplified positive photoresist discussed in U.S. Patent Application Publication No. US 2002/0045130, which contains a polyhydroxystyrene-based resin and a photoacid generating agent, as a material for the formation of a flow path pattern.

However, there were occasions in which the discharge ports of a liquid discharge head thus produced did not acquire a desired shape. According to the study by the inventor of the present invention, it was found that the acid generated from the photoacid generating agent used to make a positive type photoresist positive, remained in the pattern of flow path, and because this acid reacted with the epoxy resin in the flow path wall-forming material, the acid affected the resolution properties of the flow path wall-forming material.

### SUMMARY OF THE INVENTION

Aspects of the present invention are directed to a method for producing a liquid discharge head, which is capable of producing, with high production efficiency, a liquid discharge head having a flow path and discharge ports formed therein with high precision.

According to an aspect of the present invention, a method for producing a liquid discharge head having a flow path wall member which includes walls of a liquid flow path communicating with discharge ports that discharge a liquid, includes:

preparing a substrate provided with a resin layer formed from a resin composition containing a polyhydroxystyrene-based resin in which the hydrogen atoms of phenolic hydroxyl groups are partially substituted with groups which are dissociable by, acid, a compound having two or more vinyl ether groups, and a compound capable of generating an acid represented by formula (1) upon receiving energy from light:

A—SO₃H (1)

where A represents a substituted or unsubstituted aromatic hydrocarbon, while the substituent of the aromatic hydrocarbon does not contain fluorine;

exposing the resin layer to light and removing exposed areas to form a pattern of the flow path from the resin layer;

preparing a coating layer which serves as the flow path wall member and contains a cationically polymerizable resin and a cationic polymerization initiator, such that the coating layer covers the pattern;

exposing the coating layer to light and removing unexposed areas of the coating layer to form openings that serve as the discharge ports; and

removing the pattern to form the flow path.

According to an exemplary embodiment of the present invention, a liquid discharge head having a flow path and discharge ports formed therein with high precision can be provided with high production efficiency.

Further features and aspects of the present invention will become apparent from the following detailed description of exemplary embodiments with reference to the attached drawings.

### BRIEF DESCRIPTION OF THE DRAWINGS

The accompanying drawings, which are incorporated in and constitute a part of the specification, illustrate exemplary embodiments, features, and aspects of the invention and, together with the description, serve to explain the principles of the invention.

FIG. 1 is a schematic perspective view of a liquid discharge head according to an exemplary embodiment of the present invention.

FIGS. 2A to 2H are schematic cross-sectional views illustrating an example of a method for producing a liquid discharge head according to an exemplary embodiment of the present invention.

### DESCRIPTION OF THE EMBODIMENTS

Various exemplary embodiments, features, and aspects of the invention will be described in detail below with reference to the drawings.

The liquid discharge head according to an exemplary embodiment of the present invention can be used for industrial applications such as the manufacture of color filters, in addition to inkjet recording heads.

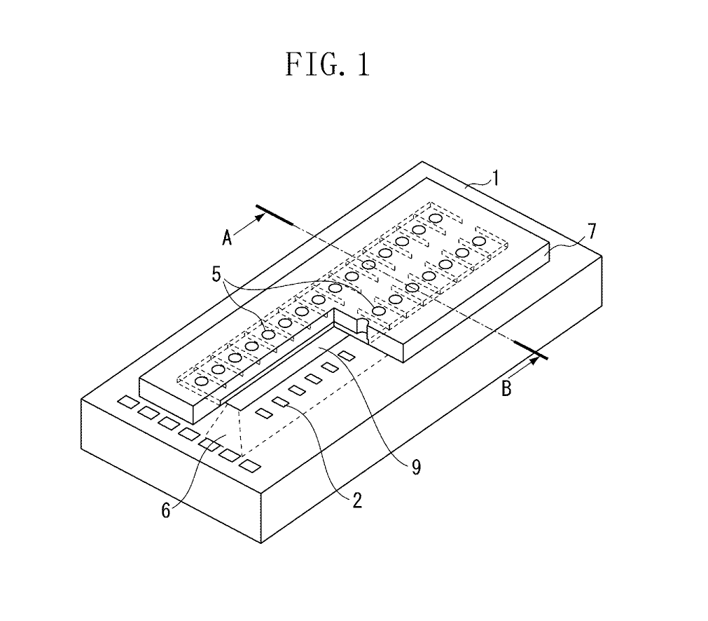

FIG. 1 is a partially transparent schematic cross-sectional diagram illustrating an example of the liquid discharge head that is produced by a method for producing a liquid discharge head according to an exemplary embodiment of the present invention. The liquid discharge head has a substrate 1 which has a plurality of energy generation elements 2, such as heaters, that are used to discharge a liquid, and further has, on the substrate 1, a flow path wall member 7 including a flow path 9 for a liquid, and discharge ports 5 for discharging ink, which communicate with the flow path 9. Furthermore, a supply port 6 which supplies a liquid to the flow path 9 is provided on the substrate 1.

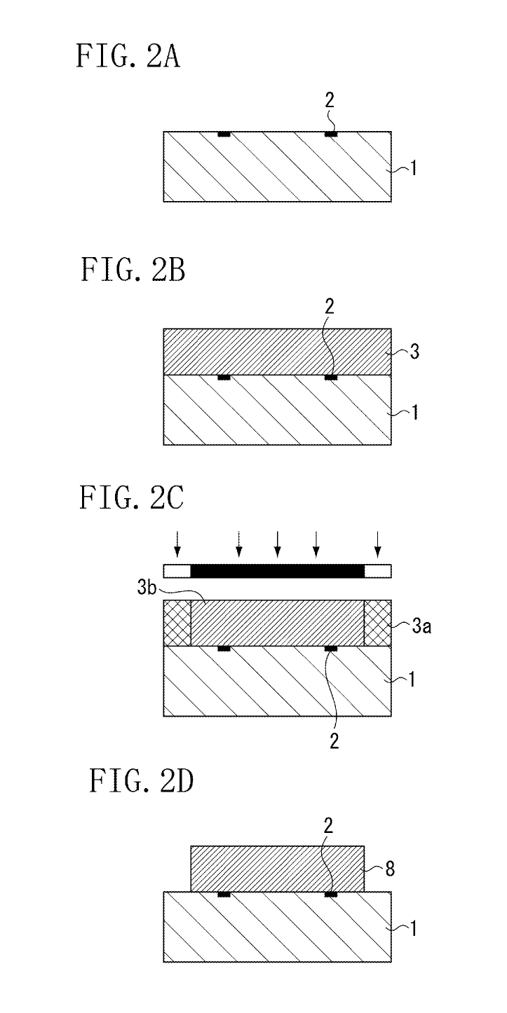

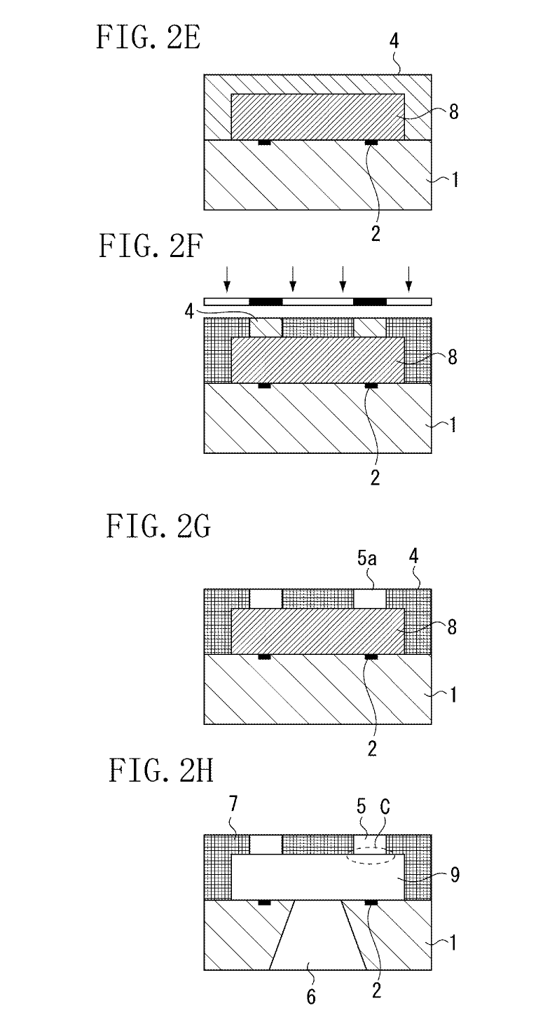

FIGS. 2A to 2H are schematic cross-sectional views illustrating the method for producing a liquid discharge head according to an exemplary embodiment of the present invention, and are schematic cut plane views illustrating the cut surfaces obtained in the respective steps when the substrate 1 is cut at a position perpendicular to the substrate 1 along the line A-B illustrated in FIG. 1.

First, a substrate 1 having energy generation elements 2 on the surface as illustrated in FIG. 2A is provided. The energy generation elements 2 are connected with a control signal input electrode (not illustrated) for operating the elements. In the case of forming a supply port on the substrate 1 by anisotropic etching, the substrate 1 is may be a silicon single crystal having crystal orientation 100. There are no particular limitations on the energy generation elements 2 as long as the elements are capable of supplying discharge energy for discharging a liquid to a liquid, and thereby discharging the liquid through discharge ports. For example, if a heat generating resistive element is used as the energy generation element 2, the heat generating resistive element heats a liquid present in the vicinity, thereby causing a change in the state of the liquid, and generates discharge energy.

A resin layer 3 of a resin composition is provided on the substrate 1 by applying the resin composition thereon through coating or the like (FIG. 2B).

The resin composition that forms this resin layer 3 contains the following components (Z1), (Z2) and (Z3):

(Z1) a polyhydroxystyrene-based resin in which at least a part of the hydrogen atoms of phenolic hydroxyl groups are protected with groups which are dissociable by acid;

(Z2) a compound having two or more vinyl ether groups; and

(Z3) a compound capable of generating an acid represented by formula (1) upon receiving energy from light:

A—SO₃H (1)

where A represents a substituted or unsubstituted aromatic hydrocarbon, and the substituent of the aromatic hydrocarbon does not contain fluorine.

The respective constituent components of the resin composition will be described in detail.

When the resin layer 3 is heated according to necessity, the component (Z1) and component (Z2) of the resin composition form a crosslinked structure. Therefore, the resin layer 3 acquires improved resistance to solvents, and the resin layer 3 hardly dissolves even if a material for the formation of flow path wall that will be described below is applied on the resin layer 3. Furthermore, when this material is irradiated with light, the acid generated from the component (Z3) (hereinafter, referred to as acid generating agent) causes decomposition of the crosslinked parts formed by the component (Z1) and the component (Z2), or decomposition of the acid-dissociable group of the component (Z1), and thereby the material becomes alkali-soluble. As a result, a pattern can be obtained by using a developer liquid containing an alkali solvent.

First, the component (Z1) will be described in detail. With regard to the component (Z1), the acid-dissociable group carried by the component (Z1) has an ability to suppress dissolution in alkali, so that the component (Z1) is substantially insoluble in alkali prior to exposure. However, in the exposed areas produced after exposure, the acid-dissociable group is dissociated under the action of the acid generated from an acid generating agent, and the solubility of the component (Z1) in an aqueous alkali solution increases. There are no particular limitations on this acid-dissociable group, but when acid-dissociability, heat resistance, and the pattern shape obtained after a photolithographic process are taken into consideration, the acid-dissociable group may be a lower alkoxyalkyl group, a tertiary alkoxycarbonyl group, or a tertiary alkoxycarbonylalkyl group. Furthermore, a tertiary alkyl group, a cyclic ether group, and the like may also be provided from the same standpoint.

Examples of the lower alkoxyalkyl group include a 1-ethoxy-1-ethyl group, and a 1-methoxy-1-propyl group. Examples of the tertiary alkoxycarbonyl group include a tert-butoxycarbonyl group, and a tert-amyloxycarbonyl group. Examples of the tertiary alkoxycarbonylalkyl group include a tert-butoxycarbonylmethyl group, a tert-butoxycarbonylethyl group, a tert-amyloxycarbonylmethyl group, and a tert-amyloxycarbonylethyl group. Examples of the tertiary alkyl group include a tert-butyl group and a tert-amyl group. Examples of the cyclic ether group include a tetrahydropyranyl group and a tetrahydrofuranyl group.

An example of the component (Z1) may be a polyhydroxystyrene in which 10% to 80% of the hydrogen atoms in hydroxyl groups are substituted with at least one kind of acid-dissociable group selected from a lower alkoxyalkyl group, a tertiary alkoxycarbonyl group, and a tertiary alkoxycarbonylalkyl group. Another example of the component (Z1) may be a polyhydroxystyrene in which 10% to 80% of the hydrogen atoms in hydroxyl groups are substituted with at least one kind of acid-dissociable group selected from a tertiary alkyl group and a cyclic ether group.

These compounds exhibit remarkable effects on the suppression of dissolution in alkali when the compounds have 10% or more of the hydrogen atoms substituted with an acid-dissociable group. Therefore, the compounds may be provided from the viewpoint that the resolution properties are enhanced. Furthermore, it may be the case that the compounds to have 80% or less of the hydrogen atoms substituted, from the viewpoint of making many crosslinking sites with the component (Z2). According to one aspect, a compound among these is a polyhydroxystyrene in which 10% to 80% of the hydrogen atoms in hydroxyl groups are substituted with a 1-ethoxy-1-ethyl group. Furthermore, a polyhydroxystyrene in which 10% to 80% of the hydrogen atoms in hydroxyl groups are substituted likewise with a tert-butoxycarbonylmethyl group, may also be provided. Similarly, a polyhydroxystyrene in which 10% to 80% of the hydrogen atoms in hydroxyl groups are substituted with a tert-butyl group, and a polyhydroxystyrene in which 10% to 80% of the hydrogen atoms in hydroxyl groups are substituted with a tetrahydropyranyl group, may also be provided. These polyhydroxystyrenes may be used singly, or two or more kinds may be used in combination. The polyhydroxystyrenes may also be copolymerized. The weight average molecular weight of these polyhydroxystyrene-based resin components is from 2,000 to 50,000, and such as from 5,000 to 25,000. The molecular weight distribution (Mw/Mn) is from 1.0 to 5.0, such as from 1.0 to 2.0. Here, the term Mw represents weight average molecular weight, and Mn represents number average molecular weight.

Next, the component (Z2) according to aspects of the present invention will be described. The component (Z2) is a compound having two or more vinyl ethers, which functions as a crosslinking agent. Any compound satisfying the requirements described above can be used without particular limitations, as long as the compound is capable of thermal crosslinking with the compound (Z1), but according to one aspect an example of the component (Z2) is a vinyl ether compound represented by the following formula (4):

R—(O—CH═CH₂)ₙ (4)

where n represents an integer from 2 to 4; and R represents an alkylene group having 1 to 30 carbon atoms, which may be substituted.

Yet another example of the component (Z2) is a vinyl ether compound in which R has an ether group. If the compound has a highly hydrophilic ether group, the component is easily miscible with the component (Z1) and is suitable for forming a smooth resin film, and, therefore, the compound is suitably used. Examples of such a compound include divinyl ethers such as triethylene glycol divinyl ether, tetramethylene glycol divinyl ether, tetraethylene glycol divinyl ether, and neopentyl glycol ethoxylate divinyl ether. Other examples include trivinyl ethers such as trimethylolpropane ethoxylate trivinyl ether, and trimethylolethane ethoxylate trivinyl ether. Other examples include trivinyl ethers such as pentaerythritol ethoxylate trivinyl ether, trimethylolpropane ethoxy ethoxylate trivinyl ether, and trimethylolpropane ethoxy ethoxy ethoxylate trivinyl ether. Other examples also include pentavinyl ethers such as erythritol ethoxylate pentavinyl ether. Among these, a trivinyl ether represented by the following formula (5) may be provided. These compounds may be used singly, or two or more kinds may be used in mixture.

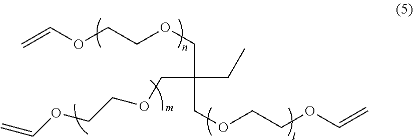

where n, m and 1 each represent a positive integer including zero, and the sum n+m+1 is from 1 to 12.

The content of this vinyl ether compound of component (Z2) is usually selected in the range of 0.1 to 300 parts by mass, such as 1 to 200 parts by mass, relative to 100 parts by mass of the component (Z1).

Finally, component (Z3) will be described.

The component (Z3) is a compound which is capable of generating an acid represented by the following formula (1) upon receiving energy from light:

A—SO₃H (1)

where A represents a substituted or unsubstituted aromatic hydrocarbon, and the substituent of the aromatic hydrocarbon does not contain fluorine.

The component (Z3) generates an acid when the compound is excited per se by directly absorbing light, or generates an acid when the component (Z3) is excited through a sensitizer which has absorbed light energy.

The component (Z3) may be a compound which can satisfactorily make positive of the resin layer 3 that has been thermally crosslinked, and is also capable of generating an acid which has less influence on the photocationically polymerizable material for forming flow path walls that are provided on the upper layer.

From this point of view, a compound capable of generating an acid represented by formula (1) is used as the component (Z3) according to aspects of the present invention.

The acid represented by the formula (1) is considered suitable because the pKa (acid dissociation constant) value of the acid is in the range of from −1.5 to 3.0. This is because, if the pKa value is less than −1.5, the acid is a strong acid and actively reacts with the cationically polymerizable group, for example, an epoxy group, in the material for the formation of flow path wall, so that there is a risk of causing curing of areas that are not the flow path walls essentially intended to be obtained. Furthermore, if the pKa value is larger than 3.0, the generated acid is a weak acid and may not bring about a sufficient reaction to make positive of the thermally crosslinked composition in the resin layer 3, and there is a risk of making the positive type resin layer 3 less sensitive. In addition, when the acid (1) contains fluorine in the substituent of the aromatic hydrocarbon, there is a possibility that the pKa value may be decreased to less than −1.5. Therefore, it is defined that the substituent of the aromatic hydrocarbon does not contain fluorine.

An example of a material for such component (Z3) is an acid generating agent that produces toluenesulfonic acid. Examples of this acid generating agent that produces toluenesulfonic acid include various compounds included in a family of compounds represented by formula (2), and among the compounds represented by the following formula (2), compounds represented by formulas (a) to (d) may be provided due to their excellent thermal stability. Even among those compounds, a compound represented by formula (a) or a compound represented by formula (b) may be provided, since sulfonium salts have superior thermal stability as compared with iodonium salts.

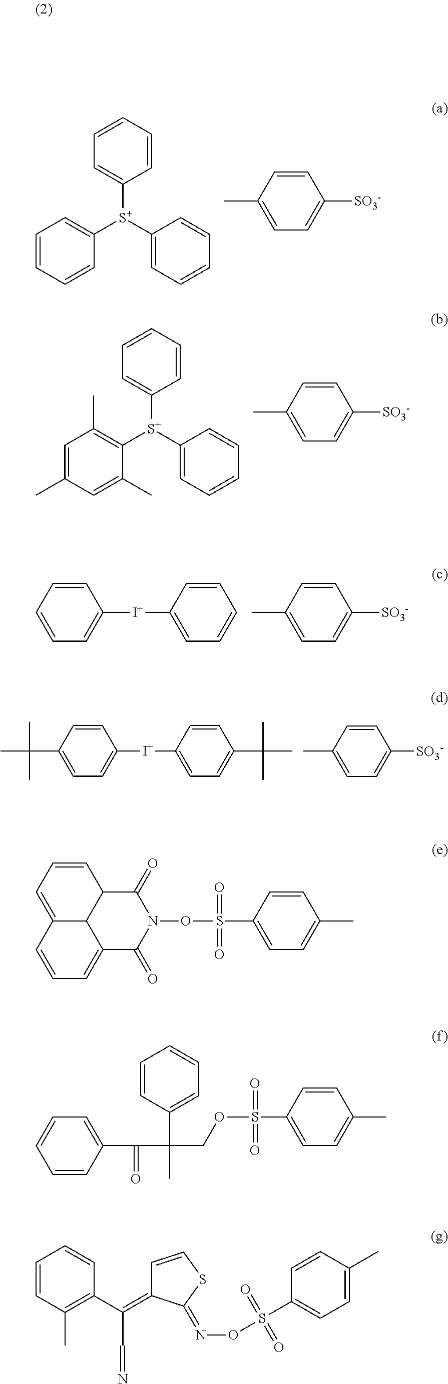

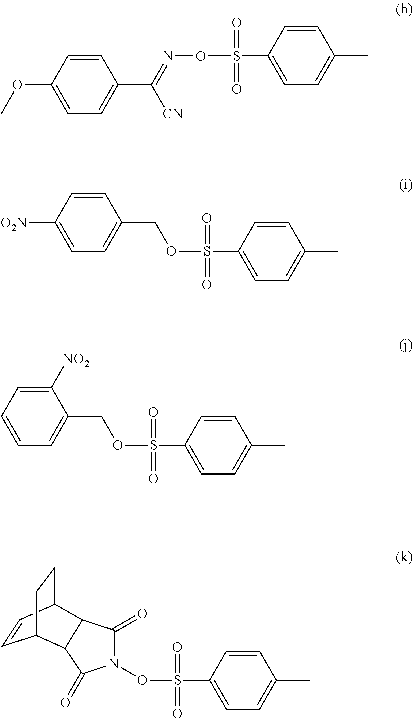

These photoacid generating agents of the component (Z3) may be used singly, or two or more kinds may be used in combination. With regard to the content of the component (Z3), an amount in the range of at least from 0.5 to 20 parts by mass relative to 100 parts by mass of the component (Z1) is sufficient for exhibiting the characteristics of the component (Z3), but the amount is not limited to this range.

The resin composition for the formation of the resin layer 3 may further contain, optionally, miscible additives, for example, those additives that are conventionally used, such as an additive resin for improving the performance of resist films, a plasticizer, a stabilizer, a colorant, and a surfactant. Furthermore, a sensitizer appropriately selected according to the exposure wavelength for exposing the resin layer 3, may also be added.

An example of the method for forming the resin layer 3 may be a method of applying a resin composition on the substrate 1, and then heating the resin composition at 90° C. to 180° C. for 30 to 600 seconds to form a layer. Thereby, thermal crosslinking between the polyhydroxystyrene-based resin (Z1) and the compound having two or more vinyl ether groups (Z2) is achieved. According to one aspect, the thermal crosslinking is carried out at 120° C. to 170° C. for 60 to 480 seconds. There are no particular limitations on the thickness of the resin layer 3, but the thickness is, for example, 2 to 50 μm. Furthermore, the resin layer 3 may also be formed by subjecting the resin composition to a heating treatment on a different substrate, performing thermal crosslinking to obtain a resin layer, and then transferring the resin layer onto the substrate 1.

Subsequently, the resin layer 3 is irradiated with light (FIG. 2C). An exposed area 3a acquires increased solubility in the developer liquid as a result of the action described above. On the other hand, an unexposed area 3b which has been partially shielded and prevented from being exposed, serves as a pattern 8 of flow path. Any exposure apparatus may be used as long as it can achieve exposure as intended, but from the viewpoint of mix-and-match, the exposure apparatus may be the same apparatus as the exposure machine used to expose a material for the formation of flow path wall that will be described below. It is also possible to use i-line as a light source, and a reduced projection type exposure machine having high mechanical precision can be used.

Subsequently, the resin layer 3 that has been exposed is subjected post-exposure baking (PEB) on a hot plate at 50° C. to 150° C., such as 60° C. to 110° C., for 30 to 600 seconds.

Subsequently, the resin layer is developed using a developer liquid to remove the exposed area 3a, and thereby a pattern 8 of flow path for liquid is formed from the resin layer 3 (FIG. 2D).

For the development, an alkaline aqueous solution such as a 0.1 wt % to 10 wt % aqueous solution of tetramethylammonium hydroxide can be used. In addition to that, an organic solvent capable of dissolving polyhydroxystyrene, such as ethanol or isopropyl alcohol (IPA), may also be used in addition to the alkaline aqueous solution. Furthermore, the resin layer may be subjected to a rinsing treatment using pure water or the like.

Subsequently, a coating layer 4 which is formed from a photocationically polymerizable, photosensitive resin composition for forming a flow path wall member is formed on the substrate 1 where the pattern 8 has been provided, such that the coating layer 4 covers the pattern 8 for the formation of flow path (FIG. 2E). The photocationically polymerizable, photosensitive resin composition that configures the coating layer 4 contains a cationically polymerizable resin having a cationically polymerizable group, and a photocationic polymerization initiator. Examples of the cationically polymerizable resin having a cationically polymerizable group include an epoxy resin, and an oxetane resin.

Examples of the epoxy resin that is used in the present exemplary embodiment include reaction products of bisphenol A and epichlorohydrin, particularly those reaction products having a molecular weight of approximately 900 or more, and reaction products of bromine-containing bisphenol A and epichlorohydrin. Furthermore, other examples include reaction products of phenol novolac or o-cresol novolac and epichlorohydrin, and the polyfunctional epoxy resin having an oxycyclohexane skeleton discussed in Japanese Patent Application Laid-Open No. 2-140219, but the examples are not limited to these compounds.

With regard to the epoxy resin described above, a compound having an epoxy equivalent of 2000 or less, such as an epoxy equivalent of 1000 or less, is suitably used. This is because, if the epoxy equivalent exceeds 2000, the crosslinking density decreases at the time of the curing reaction, and issues may occur with adhesiveness and liquid resistance.

As the photocationic polymerization initiator for curing the epoxy resin, a compound which generates an acid when irradiated with light can be used, and specific examples include an aromatic sulfonium salt and an aromatic iodonium salt. More specifically, SP-150, SP-170, SP-172 and the like commercially available from ADEKA Corporation can be suitably used.

Furthermore, the photocationically polymerizable photosensitive resin composition that constitutes the coating layer 4 can optionally contain appropriate additives. For example, a flexibility imparting agent may be added for the purpose of lowering the elastic modulus of the epoxy resin, or a silane coupling agent may be added to obtain additional adhesive power to the foundation.

As the method for providing a coating layer 4 on the pattern 8, for example, a method of appropriately dissolving a photocationically polymerizable, photosensitive resin composition in a solvent such as xylene or diglyme, and applying the solution on the pattern 8 and the substrate 1 by a spin coating method or the like. Thereafter, the applied solution is prebaked, and thereby a coating layer 4 can be formed. The thickness of the coating layer 4 may be 2 μm or more as the thickness on the pattern 8, since a certain degree of mechanical strength is needed by the flow path walls. Furthermore, the upper limit of the thickness is not particularly limited as long as the developability of the discharge ports that are formed later is not impaired. However, it is thought that sufficient developability may be obtained if the thickness of the coating layer 4 as the thickness on the pattern 8 is 100 μm or less.

Subsequently, the coating layer 4 is irradiated with light to cure the exposed areas of the coating layer 4 (FIG. 2F). At the areas irradiated with light, a cationic active species is produced from the photocationic polymerization initiator, and as the photocationically polymerizable resin undergoes cationic polymerization, curing proceeds. Since the areas where discharge ports are expected to be formed, will be removed later by development, those areas are shielded by using a mask to prevent exposure. Curing may be accelerated by performing heating.

Thereafter, development is carried out using methyl isobutyl ketone (MIBK), xylene or the like, and unexposed areas are removed to thereby form openings 5a that will serve as discharge ports, on the coating layer 4. Optionally, a rinsing treatment using isopropyl alcohol (IPA) or the like may also be carried out (FIG. 2G).

Subsequently, the substrate is subjected to etching to form a supply port 6, and the pattern 8 is removed by dissolving in an appropriate solvent to form a flow path 9 that communicates with the discharge ports 5. Thus, a flow path wall member 7 is obtained (FIG. 2H). At this time, the pattern 8 is irradiated with light to decompose the crosslinked areas of the pattern 8, and after the light irradiation, the pattern 8 may also be subjected to a heating treatment and then be dissolved in an appropriate solvent. Any method other than the method described above can also be used as long as the gist according to aspects of the present invention is maintained. Furthermore, the term appropriate solvent as used herein may be an aqueous alkaline solution or may be an organic solvent.

Thereafter, the substrate 1 is separated by cutting using a dicing saw or the like, to be produced into chips, and electrical bonding intended to drive the energy generation elements 2 is carried out. Furthermore, an external member for supplying a liquid is connected to the discharge ports 6, and thus a liquid discharge head is completed.

Hereinafter, aspects of the present invention will be described in detail by way of Examples. However, the present invention is not intended to be limited to these Examples. The liquid discharge heads of Examples and Comparative Examples were produced by the method that will be described below.

### Example 1

First, a silicon (Si) substrate 1 having a plurality of energy generation elements 2 provided on one surface was prepared (FIG. 2A).

Subsequently, a resin composition illustrated below was prepared as a resin composition for pattern formation.

(Z1) A polyhydroxystyrene in which 30% of the hydrogen atoms in phenolic hydroxyl groups are substituted with tert-butyl groups (t-Bu) 100 parts by mass;

(Z2) Trimethylolpropane ethoxylate trivinyl ether (BEI) 100 parts by mass; and

(Z3) TPS-1000 (trade name, manufactured by Midori Kagaku Co., Ltd.) 2 parts by mass.

In addition, a photosensitizer (trade name: SP-100, manufactured by ADEKA Corporation) was added commonly to the respective Examples and the respective Comparative Examples, in an amount of 1 part by mass relative to the mass of the component (Z1) to increase the photosensitivity of the resin composition. The photosensitizer was an anthracene compound.

Here, the acid generated when TPS-1000 is subjected to the action of light is toluenesulfonic acid, and the pKa value of toluenesulfonic acid is −0.43±0.50 (value calculated by using pKaDB (trade name: manufactured by Fujitsu, Ltd.)).

Next, the resin composition was applied on the substrate 1 and was baked for 5 minutes at 150° C., and thereby a resin layer 3 having a thickness of 5 μm was formed (FIG. 2B). Furthermore, the solvent component in this resin composition was propylene glycol monomethyl ether acetate (PGMEA).

Thereafter, the resin layer 3 was exposed using an i-line stepper (manufactured by Canon, Inc.) (FIG. 2C).

Subsequently, the assembly was subjected to PEB for 5 minutes at 80° C., and development was carried out using a 2.34 wt % aqueous solution of tetramethylammonium hydroxide. Rinsing was carried out using pure water, and thus the pattern 8 was obtained (FIG. 2D).

Subsequently, a photocationically polymerizable resin composition for the formation of flow path walls (having the following composition), which used an epoxy resin as a cationically polymerizable resin, was spin-coated on the pattern 8, and thus the coating layer 4 was formed (FIG. 2E). Diglyme was used as the solvent.

(Photocationically Polymerizable Resin Composition for Formation of Flow Path Walls)

Cationically polymerizable resin: Epoxy resin indicated in Table 1 100 parts by mass

Photocationic polymerization initiator: SP-172 (trade name, manufactured by ADEKA Corporation) 2 parts by mass

Silane coupling agent: A-187 (trade name, manufactured by Nippon Unicar Co., Ltd.) 5 parts by mass

In the Examples and Comparative Examples that follow, the mass ratio of cationically polymerizable resin:photocationic polymerization initiator:silane coupling agent is 100:2:5.

Subsequently, the assembly was exposed (FIG. 2F) using an i-line stepper (manufactured by Canon, Inc.), and was subjected to PEB for 4 minutes at 90° C. Subsequently, openings 5a having a diameter of 15 μm, which served as discharge ports, were formed using MIBK as a developer liquid (FIG. 2G).

Subsequently, a discharge port 6 was formed, and the pattern 8 was removed to thereby form a flow path 9 (FIG. 2H). Finally, the assembly was heated for one hour at 200° C. to more certainly cure the flow path wall member. Thus, a liquid discharge head was obtained.

### Example 2

A liquid discharge head was produced in the same manner as in Example 1, except that the epoxy resin for the formation of flow path walls was changed from EHPE3150 to JER157 (trade name, manufactured by Japan Epoxy Resins Co., Ltd.).

### Example 3

A liquid discharge head was produced in the same manner as in Example 1, except that WPAG-367 (trade name, manufactured by Wako Pure Chemical Industries, Ltd.) was used instead of TPS-1000 as the component (Z3) in the resin composition for pattern formation. Here, the acid generated when WPAG-367 is irradiated with light is toluenesulfonic acid, and the pKa value of toluenesulfonic acid is −0.43±0.50 (value calculated by using pKaDB (trade name: manufactured by Fujitsu, Ltd.)).

### Example 4

A liquid discharge head was produced in the same manner as in Example 1, except that WPAG-367 was used instead of TPS-1000 as the component (Z3) in the resin composition for pattern formation, and the epoxy resin for the formation of flow path walls was changed from EHPE3150 to JER157.

### Example 5

A liquid discharge head was produced in the same manner as in Example 1, except that a polyhydroxystyrene in which 30% of the hydrogen atoms in phenolic hydroxyl groups are substituted with tert-butoxycarbonyl groups (TBOC), was used instead of t-Bu as the component (Z1) in the resin composition for pattern formation.

### Example 6

A liquid discharge head was produced in the same manner as in Example 1, except that TBOC was used instead of t-Bu as the component (Z1) in the resin composition for pattern formation, and the epoxy resin for the formation of flow path walls was changed from EHPE3150 to JER157.

### Example 7

A liquid discharge head was produced in the same manner as in Example 1, except that TBOC was used instead of t-Bu as the component (Z1) in the resin composition for pattern formation, and WPAG-367 was used instead of TPS-1000 as the component (Z3).

### Example 8

A liquid discharge head was produced in the same manner as in Example 1, except that TBOC was used instead of t-Bu as the component (Z1) in the resin composition for pattern formation, WPAG-367 was used instead of TPS-1000 as the component (Z3), and the epoxy resin for the formation of flow path walls was changed from EHPE3150 to JER157.

### Comparative Example 1

A liquid discharge head was produced in the same manner as in Example 1, except that TPS-109 (trade name, manufactured by Midori Kagaku Co., Ltd.) was used instead of TPS-1000 which was used as the component (Z3) in Example 1 as the photoacid generating agent component in the resin composition for pattern formation. Here, the acid generated when TPS-109 is irradiated with light is perfluorobutanesulfonic acid, and the pKa value of perfluorobutanesulfonic acid is −0.43±0.50 (value calculated by using pKaDB (trade name: manufactured by Fujitsu, Ltd.)).

### Comparative Example 2

A liquid discharge head was produced in the same manner as in Example 5, except that TPS-109 (trade name, manufactured by Midori Kagaku Co., Ltd.) was used instead of TPS-1000 used as the component (Z3) in Example 1 as the photoacid generating agent component in the resin composition for pattern formation.

### Comparative Example 3

An attempt was made to produce a liquid discharge head in the same manner as in Example 1, except that TPS-Acetate (trade name, manufactured by Midori Kagaku Co., Ltd.) was used instead of TPS-1000 used as the component (Z3) in Example 1 as the photoacid generating agent component in the resin composition for pattern formation. Here, the acid generated when TPS-Acetate is irradiated with light is acetic acid, and the pKa value of acetic acid is 4.79±0.10 (value calculated by using pKaDB (trade name: manufactured by Fujitsu, Ltd.)).

However, the pattern of flow path was not formed into a predetermined pattern, and the production of a liquid discharge head was stopped.

For each of the liquid discharge heads obtained by the production methods of the respective Examples and the liquid discharge heads obtained by the production methods of the respective Comparative Examples, the communicating part between the discharge ports and the flow path (part C surrounded by dotted and dashed line in FIG. 2H) was evaluated by observing with a scanning electron microscope. The evaluation results are as follows.

◯: Excess residues were not found at the communicating part between the discharge ports and the flow path, and edges of the discharge ports at the relevant areas were sharp.

Δ: Solid films deposited on the communicating part between the discharge ports and the flow path were found.

A summary of the materials used in the respective Examples and evaluation results is illustrated in Table 1.

TABLE 1

| | | | | | Material | |
|---|---|---|---|---|---|---|
| | | | | | for | |
| | | Resin composition for pattern | | | formation | |
| | | formation | | | of flow | |
| | | Component | Component | Component | path walls | |
| | | (Z1) | (Z2) | (Z3) (parts | Epoxy | |
| | | (parts by mass) | (parts by mass) | by mass) | resin | Evaluation |
| Example | 1 | t-Bu | BEI | TPS-1000 | EHPE3150 | ◯ |
| | | (100) | (100) | (2) | | |
| | 2 | t-Bu | BEI | TPS-1000 | JER157 | ◯ |
| | | (100) | (100) | (2) | | |
| | 3 | t-Bu | BEI | WPAG-367 | EHPE3150 | ◯ |
| | | (100) | (100) | (2) | | |
| | 4 | t-Bu | BEI | WPAG-367 | JER157 | ◯ |
| | | (100) | (100) | (2) | | |
| | 5 | TBOC | BEI | TPS-1000 | EHPE3150 | ◯ |
| | | (100) | (100) | (2) | | |
| | 6 | TBOC | BEI | TPS-1000 | JER157 | ◯ |
| | | (100) | (100) | (2) | | |
| | 7 | TBOC | BEI | WPAG-367 | EHPE3150 | ◯ |
| | | (100) | (100) | (2) | | |
| | 8 | TBOC | BEI | WPAG-367 | JER157 | ◯ |
| | | (100) | (100) | (2) | | |
| | | | | Photoacid | Material | |
| | | | | generating | for | |
| | | | Crosslinking | agent | formation | |
| | | Base resin | agent (parts | (parts by | of flow | |
| | | (parts by mass) | by mass) | mass) | path walls | Evaluation |
| Comparative | 1 | t-Bu | BEI | TPS-109 | EHPE3150 | Δ |
| Example | | (100) | (100) | (2) | | |
| | 2 | TBOC | BEI | TPS-109 | EHPE3150 | Δ |
| | | (100) | (100) | (2) | | |
| | 3 | t-Bu | BEI | TPS-Acetate | EHPE3150 | Δ |
| | | (100) | (100) | (2) | | |

The abbreviations and trade names indicated in Table 1 are as follows.

[Resin Composition for Pattern Formation]

As component (Z1)

t-Bu: Polyhydroxystyrene in which 30% of the hydrogen atoms of phenolic hydroxylgroups are substituted with tert-butyl groups

TBOC: Polyhydroxystyrene in which 30% of the hydrogen atoms of phenolic hydroxyl groups are substituted with tert-butoxycarbonyl groups

As component (Z2)

BEI: Trimethylolpropane ethoxylate trivinyl ether

Explanations for the component (Z3) of the Examples, and the compounds used as the photoacid generating agent of the Comparative Examples are indicated in Table 2.

In addition, TPS-1000 is a compound represented by formula (a) in the formula (2) described above, and WPAG-367 is a compound represented by formula (b) of the formula (2).

TABLE 2

| | Compound | Acid generated | pKa * |
|---|---|---|---|
| Component (Z3) | TPS-1000 | Toluenesulfonic | −0.43 ± 0.50 |
| of Examples 1, | (trade name, | acid | |
| 2, 5, and 6 | manufactured | | |
| | by Midori | | |
| | Kagaku Co., | | |
| | Ltd.) | | |
| Component (Z3) | WPAG-367 | Toluenesulfonic | −0.43 ± 0.50 |
| of Examples 3, | (trade name, | acid | |
| 4, 7, and 8 | manufactured | | |
| | by Wako Pure | | |
| | Chemical | | |
| | Industries, Ltd.) | | |
| Photoacid | TPS-109 (trade | Perfluorobutane- | −3.75 ± 0.50 |
| generating | name, | sulfonic acid | |
| agent in | manufactured | | |
| pattern | by Midori | | |
| forming | Kagaku Co., | | |
| material of | Ltd.) | | |
| Comparative | | | |
| Examples 1 and | | | |
| 2 | | | |
| Photoacid | TPS-Acetate | Acetic acid | 4.79 ± 0.10 |
| generating | (trade name, | | |
| agent in | manufactured | | |
| pattern | by Midori | | |
| forming | Kagaku Co., | | |
| material of | Ltd.) | | |
| Comparative | | | |
| Example 3 | | | |

* Value calculated by using pKaDB (trade name, manufactured by Fujitsu, Ltd.)

[Material for Formation of Flow Path Walls]

(Epoxy Resin)

EHPE3150 (Polyfunctional epoxy resin; trade name, manufactured by Daicel Chemical Industries, Ltd.)

JER157 (Bisphenol A-type novolac-type polyfunctional epoxy resin; manufactured by Japan Epoxy Resins Co., Ltd.)

The films deposited between the discharge ports and the flow path observed in Comparative Examples 1 and 2 are thought to be formed of the same material as that used for the flow path wall member, and a cured product of the coating layer. It is thought that these films have been cured by the action of the acid generated from TPS-109 used as a photoacid generating agent of the material for pattern formation in Comparative Examples 1 and 2. This is thought to be because perfluorobutanesulfonic acid, which is the acid generated from TPS-109, has a pKa value of −3.57±0.50, which is −1.5 or less, and is a very strong acid, and, therefore, this strong acid remaining in the pattern 8 and the epoxy groups of the epoxy resin in the material for the formation of flow path walls react with each other to cause curing even at unexposed areas inside the coating layer, thereby making the unexposed areas insoluble to the developer liquid.

Furthermore, in Comparative Example 3, development was carried out after the material for pattern formation was exposed, but only the surface part of the areas that were wished to be removed after development was removed, and the pattern 8 could not be formed. This is thought to be because the acetic acid generated from TPS-Acetate used as the photoacid generating agent of the material for pattern formation has a pKa value of 4.79±0.10, which is 3.0 or higher, and is a weak acid, and, therefore, the progress of the reaction to make the exposed areas positive was insufficient.

Furthermore, in Examples 1 to 8, there were no residual films deposited between the flow path and the discharge ports of the liquid discharge head, and a discharge port shape with sharp edges in the communicating part was obtained. The acid generated from the component (Z3) used in the Examples had a pKa value of −0.43±0.50, which was from −1.5 to 3.0. The strength of this acid was sufficient for the reaction of making the photoresist positive for the formation of the pattern 8, and was an appropriate strength with less influence of the residues on the coating layer 4. Therefore, it is thought that satisfactory results were obtained thereby.

While the present invention has been described with reference to exemplary embodiments, it is to be understood that the invention is not limited to the disclosed exemplary embodiments. The scope of the following claims is to be accorded the broadest interpretation so as to encompass all modifications, equivalent structures, and functions.

This application claims priority from Japanese Patent Application No. 2010-085464 filed Apr. 1, 2010, which is hereby incorporated by reference herein in its entirety.

What is claimed is:

1. A method for producing a liquid discharge head having a flow path wall member which includes walls of a liquid flow path communicating with discharge ports that discharge a liquid, the method comprising:
preparing a substrate provided with a resin layer formed from a resin composition containing a polyhydroxystyrene-based resin in which the hydrogen atoms of phenolic hydroxyl groups are partially substituted with groups which are dissociable by acid, a compound having two or more vinyl ether groups, and a compound capable of generating an acid represented by formula (1) upon receiving energy from light:
A—SO₃H (1)
where A represents a substituted or unsubstituted aromatic hydrocarbon, while the substituent of the aromatic hydrocarbon does not contain fluorine;
exposing the resin layer to light and removing exposed areas to form a pattern of the flow path from the resin layer;
preparing a coating layer which serves as the flow path wall member and contains a cationically polymerizable resin and a cationic polymerization initiator, such that the coating layer covers the pattern;
exposing the coating layer to light and removing unexposed areas of the coating layer to form openings that serve as the discharge ports; and
removing the pattern to form the flow path.

2. The method according to claim 1, wherein the acid is toluenesulfonic acid.

3. The method according to claim 1, wherein the compound capable of generating the acid is at least one selected from the compounds represented by formulas (a) to (k):

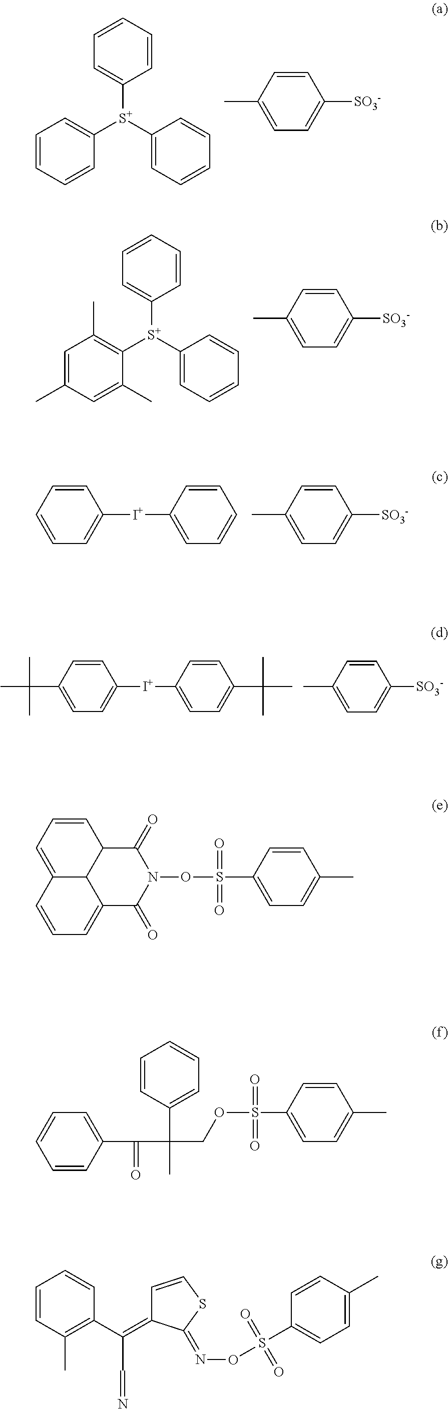

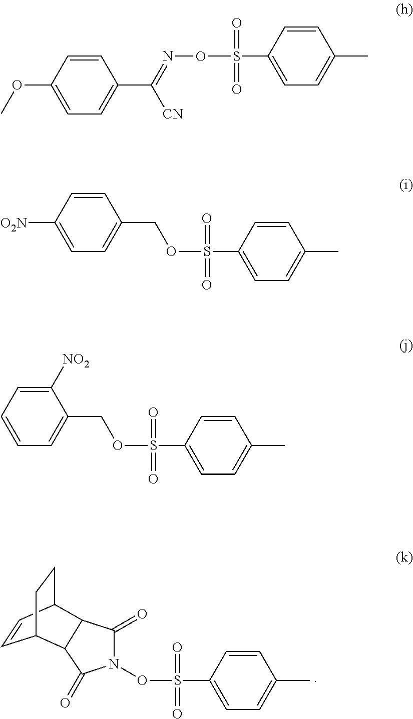

4. The method according to claim 1, wherein the compound capable of generating the acid is at least one selected from the compounds represented by formulas (a) to (d):

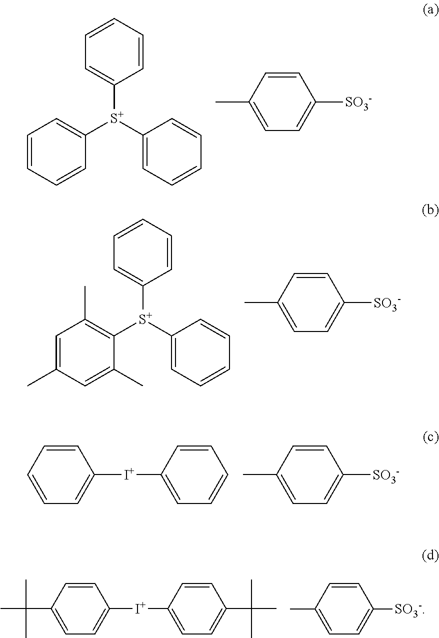

5. The method according to claim 3, wherein the compound capable of generating the acid is a compound represented by formula (a) or formula (b).

6. The method according to claim 1, wherein the resin layer is exposed to i-line.

7. The method according to claim 1, wherein the coating layer is exposed to i-line.

8. The method according to claim 1, wherein the acid represented by the formula (1) has a pKa value of from −1.5 to 3.0.

9. A photosensitive resin composition for formation of a flow path of a liquid discharge head, the photosensitive resin composition comprising:
a polyhydroxystyrene-based resin in which the hydrogen atoms of phenolic hydroxyl groups are partially substituted with groups which are dissociable by acid;
a compound having two or more vinyl ether groups; and
a compound capable of generating an acid represented by formula (1) upon receiving energy from light:
A—SO₃H (1)
where A represents a substituted or unsubstituted aromatic hydrocarbon, while the substituent of the aromatic hydrocarbon does not contain fluorine.
